(19) United States
(12) Patent Application Publication
(10) Pub. No.: US 2026/0304701 A1
(43) Pub. Date: Oct. 1, 2026

(54) HEAT SINK WITH A HOT SIDE PISTON, A COLD SIDE PISTON, AND A SHAFT CONNECTING THE PISTONS

(71) Applicant: Raytheon Company, Arlington, VA (US)

(72) Inventors: Andrzej E. Kuczek, Bristol, CT (US); Matthew R. Pearson, Hartford, CT (US); Yasmin Khakpour, South Windsor, CT (US); Jason G. Milne, El Segundo, CA (US)

(21) Appl. No.: 19/091,079

(22) Filed: Mar. 26, 2025

(51) Int. Cl. H05K 7/20

(52) U.S. Cl. CPC H05K 7/2039; H05K 7/20327

(57) ABSTRACT

A heat sink assembly, having: a housing with a first plate, a second plate, and a sidewall extending therebetween, the housing defines a fluid circuit, a first leg of the circuit extending within the housing along the first plate, and a runner leg of the circuit extending within the housing along the sidewall; a two-phase fluid is in the circuit; a first reservoir, defined by a first piston skirt having a first piston area, fluidly coupled to the first leg of the circuit, and a first piston head located in the first reservoir; a second reservoir, defined by a second piston skirt having a second piston area, fluidly coupled to the runner leg of the fluid circuit, the second piston area is larger than the first piston area, and a second piston head is located in the second reservoir; and a connecting rod connecting the second and first piston heads.

### BACKGROUND

The embodiments are directed to a heat sink for electronics and more specifically to a heat sink with a hot side piston, a cold side piston, and a shaft connecting the pistons.

As computing capabilities improve and applications call on electronics, such as microelectronics for increasingly complex and computationally expensive operations, power draw and heat rejection in these devices can be a limiting factor. Furthermore, many products operate under constraints on size, weight, and power (SWaP) that can limit the mitigation strategies available for a cooling system design.

### BRIEF SUMMARY

Disclosed a heat sink assembly, including: a housing having a first plate that receives a heat load, a second plate that is a cooling plate, and a sidewall extending from the first plate to the second plate, wherein the housing defines a fluid circuit, with a first leg of the fluid circuit extending within the housing along the first plate, and a runner leg of the fluid circuit extending within the housing along the sidewall; a two-phase fluid in the fluid circuit; a first reservoir, defined by a first piston skirt having a first piston area, fluidly coupled to the first leg of the fluid circuit, and a first piston head is located in the first reservoir; a second reservoir, defined by a second piston skirt having a second piston area, fluidly coupled to the runner leg of the fluid circuit, wherein the second piston area is larger than the first piston area, and a second piston head is located in the second reservoir; and a connecting rod connecting the second and first piston heads.

In addition to one or more above disclosed aspects of the assembly or as an alternate, the first reservoir is cylindrically shaped.

In addition to one or more above disclosed aspects of the assembly or as an alternate, the second reservoir is cylindrically shaped.

In addition to one or more above disclosed aspects of the assembly or as an alternate, the first leg of the fluid circuit is defined by an inner first wall; the runner leg of the fluid circuit is defined by an inner sidewall; the first reservoir is defined by a first reservoir wall extending to a second end; and the second reservoir is defined at least partially by the inner sidewall.

In addition to one or more above disclosed aspects of the assembly or as an alternate, a segment of the inner sidewall is isolated from the runner leg of the fluid circuit and defines an aperture such that the second and first piston heads and the connecting rod are exposed to atmospheric pressure, to bias the second piston head toward the second plate.

In addition to one or more above disclosed aspects of the assembly or as an alternate, a biasing member extends from the second end of the first reservoir wall toward the second piston head.

In addition to one or more above disclosed aspects of the assembly or as an alternate, the biasing member is a spring.

In addition to one or more above disclosed aspects of the assembly or as an alternate, the inner first wall defines a first flow aperture having a first flow aperture area that is smaller than the first piston area, for flow between the first reservoir and the fluid circuit.

In addition to one or more above disclosed aspects of the assembly or as an alternate, the inner sidewall defines a sidewall flow aperture for flow between the second reservoir and the fluid circuit.

In addition to one or more above disclosed aspects of the assembly or as an alternate, in operation: a change of the two-phase fluid to gas in the first leg of the fluid circuit causes the gas to move upward to the second reservoir via the runner leg, forcing the second and first piston heads to move downward as the gas fills the second reservoir and additional fluid from the first reservoir enters the first leg of the fluid circuit; and cooling of the second plate changes the gas to the two-phase fluid, whereby the two-phase fluid flows via the runner leg of the fluid circuit, into the first leg of the fluid circuit and into the first reservoir, and the second and first piston heads are biased upwardly.

In addition to one or more above disclosed aspects of the assembly or as an alternate, the assembly includes an exterior heat sink connected to the second plate.

In addition to one or more above disclosed aspects of the assembly or as an alternate, the exterior heat sink is a conductive or convective heat sink.

Further disclosed is a heat sink assembly according to another embodiment, including: a first plate that receives a heat load, a second plate that is a cooling plate and is supported so as to be spaced apart from the first plate, and a tube extending from the first plate to the second plate, wherein the assembly defines a fluid circuit, with a first leg of the fluid circuit extending within the first plate, and a runner leg of the fluid circuit extending within the tube; a two-phase fluid in the fluid circuit; a first reservoir, defined by a first piston skirt having a first piston area, fluidly coupled to the first leg of the fluid circuit, and a first piston head is located in the first reservoir; a second reservoir, defined by a bellow piston having a second piston head that is hat-shaped such that the second piston head has a piston inner surface and a piston first flange, and an exterior bellow sleeve coupled between the second plate and the piston first flange of the second piston head, wherein a cavity between the second piston head and the bellow sleeve defines the second reservoir, a connecting rod connecting the second and first piston heads.

In addition to one or more above disclosed aspects of the assembly according to the another embodiment, or as an alternate, the first reservoir is cylindrically shaped.

In addition to one or more above disclosed aspects of the assembly according to the another embodiment, or as an alternate, the first plate defines a first flow aperture defining a first flow aperture area that is smaller than the first piston area, for flow between the first reservoir and the fluid circuit.

In addition to one or more above disclosed aspects of the assembly according to the another embodiment, or as an alternate, the second plate defines a second flow aperture for flow between the second reservoir and the fluid circuit.

In addition to one or more above disclosed aspects of the assembly according to the another embodiment, or as an alternate, in operation: a change of the two-phase fluid to gas in the first leg of the fluid circuit causes the gas to move upward to the second reservoir via the runner leg, forcing the second and first piston heads to move downward as the gas fills the second reservoir and additional fluid from the first reservoir enters the first leg of the fluid circuit; and cooling of the second plate or the bellow sleeve changes the gas to the two-phase fluid, whereby the two-phase fluid flows via the runner leg of the fluid circuit, into the first leg of the fluid circuit and into the first reservoir, and the second and first piston heads are biased upwardly.

In addition to one or more above disclosed aspects of the assembly according to the another embodiment, or as an alternate, the assembly includes an exterior heat sink operationally coupled to the second plate or the bellow sleeve.

In addition to one or more above disclosed aspects of the assembly according to the another embodiment, or as an alternate, the exterior heat sink is a conductive or convective heat sink.

### BRIEF DESCRIPTION OF THE DRAWINGS

The following descriptions should not be considered limiting in any way. With reference to the accompanying drawings, like elements are numbered alike:

FIG. 1 is a sideview of a heat sink according to an embodiment;

FIG. 2A is a view of the heat sink of FIG. 1 in which the working fluid is in a liquid state and the top piston is retracted;

FIG. 2B is a view of the heat sink in which the working fluid is in a two phase state and the top piston is not yet advanced;

FIG. 2C is a view of the heat sink in which the working fluid is in the two phase state and the top piston is advanced;

FIG. 2D is a view of the heat sink in which the working fluid is in the liquid state and the top piston is being retracted;

FIG. 2E shows the different stages of heat transfer that occur utilizing the heat sink;

FIG. 3A is a sideview of a heat sink according to another embodiment;

FIG. 3B is another sideview of the heat sink;

FIG. 4A is a view of the heat sink of FIGS. 3A and 3B in which the working fluid is in a liquid state and the top piston is retracted;

FIG. 4B is a view of the heat sink in which the working fluid is in a two phase state and the top piston is not yet advanced;

FIG. 4C is a view of the heat sink in which the working fluid is in the two phase state and the top piston is advanced;

FIG. 4D is a view of the heat sink in which the working fluid is in the liquid state and the top piston is retracted; and

FIG. 4E shows the different stages of heat transfer that occur utilizing the heat sink.

### DETAILED DESCRIPTION

A detailed description of one or more embodiments of the disclosed apparatus and method are presented herein by way of exemplification and not limitation with reference to the Figures.

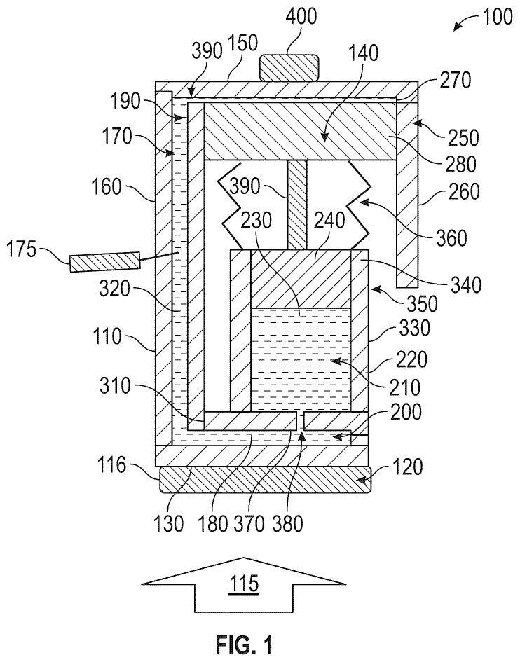

Turning to FIG. 1, a heat sink assembly 100 is shown. The assembly 100 includes a housing 110. The housing 110 has a hot side 120 with a bottom (first) plate 130 that receives a heat load 115, e.g., from electronics 116. The housing 110 has a cold side 140 with a top (second) plate 150 that is a cooling plate. A sidewall 160 extends from the bottom plate 130 to the top plate 150.

The housing 110 defines a fluid circuit 170 with different legs or channels. The fluid circuit 170 has a bottom (first) leg 180 extending within the housing 110 along the bottom plate 130. A runner leg 190 of the fluid circuit 170 extends within the housing 110 along the sidewall 160. A two-phase fluid 200 is located in the fluid circuit 170. The fluid 200 may be a refrigerant, alcohol, water, or the like.

A bottom (first) reservoir 210 is defined by a bottom (first) piston skirt 220 having a bottom (first) piston area 230. A bottom (first) piston head 240 is located in the bottom reservoir 210, guided by the bottom piston skirt 220. The bottom reservoir 210 is fluidly coupled to the bottom leg 180 of the fluid circuit 170.

A top (second) reservoir 250 is defined by a top (second) piston skirt 260 having a top (second) piston area 270. A top (second) piston head 280 is located in the top reservoir 250, guided by the top piston skirt 260. The top reservoir 250 is fluidly coupled to the runner leg 190 of the fluid circuit 170. The top piston area 270 is larger than the bottom piston area 230. A connecting rod 300 connects the top and bottom piston heads 280, 240. In one embodiment, the bottom reservoir 210 and the top reservoir 250 are cylindrically shaped.

The fluid 200 maybe filled within the circuit 170 to provide enough buoyancy to the top and bottom piston heads 280, 240 so as to prevent downward movement when the fluid 200 is entirely in a liquid form. The fluid 200 may be, e.g., injected into the circuit 170, such as by a plunger 175, and any opening from such injection may be sealed before the assembly 100 is placed in service.

The bottom leg 180 of the fluid circuit 170 is defined by an inner bottom wall 310. The runner leg 190 of the fluid circuit 170 is defined by an inner sidewall 320. The bottom reservoir 210 is defined by a bottom (first) reservoir wall 330 that defines the bottom piston skirt 220 and extends to a top (second) end 340. The top reservoir 250 is defined at least partially by the inner sidewall 320, which at least partially defines the top piston skirt 260.

A segment of the inner sidewall 320 is isolated from the runner leg 190 of the fluid circuit 170 and defines an aperture 350 such that the top and bottom piston heads 280, 240 and connecting rod 300 are exposed to atmospheric pressure. This configuration biases the top piston head 280 toward the top plate 150 due to the different sizes of the piston heads. A biasing member 360 may extend from the top end 340 of the bottom reservoir wall 330 toward the top piston head 280. The biasing member 360 may be a spring and more specifically a coil spring. The biasing member 360 may provide supplemental biasing forces in conditions of low atmospheric pressure, to bias the top piston head 280 toward the top plate 150.

The inner bottom wall 310 defines a bottom (first) flow aperture 370 having a bottom (first) flow aperture area 380 that is smaller than the bottom piston area 230 to form a dispensing nozzle. The bottom flow aperture 370 provides for flow between the bottom reservoir 210 and the fluid circuit 170. The inner sidewall 320 defines a sidewall flow aperture 390 that is adjacent to the top plate 150 for flow between the top reservoir 250 and the fluid circuit 170.

An exterior heat sink 400 may be connected to the top plate 150. The exterior heat sink 400 may be a conductive or convective heat sink, such as a fan or a cold plate.

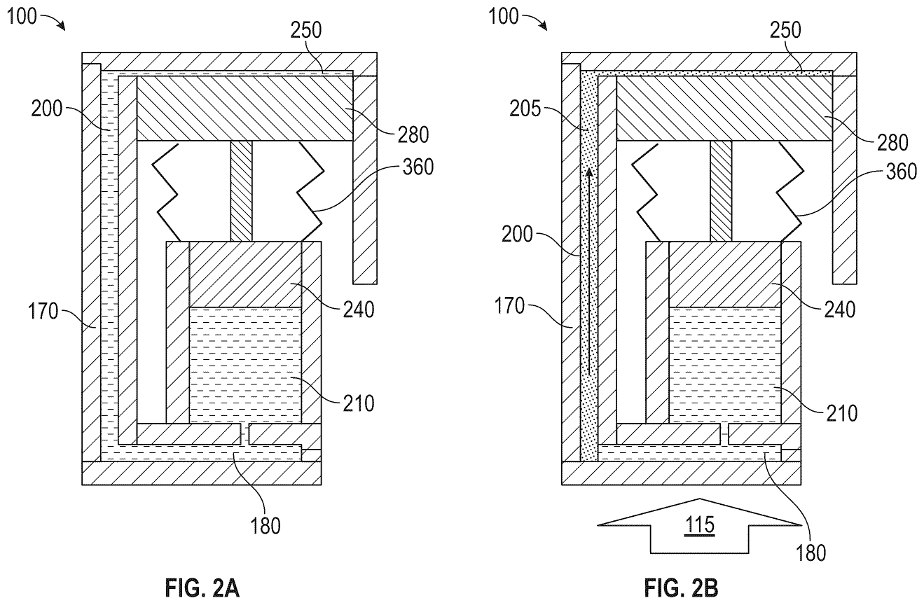

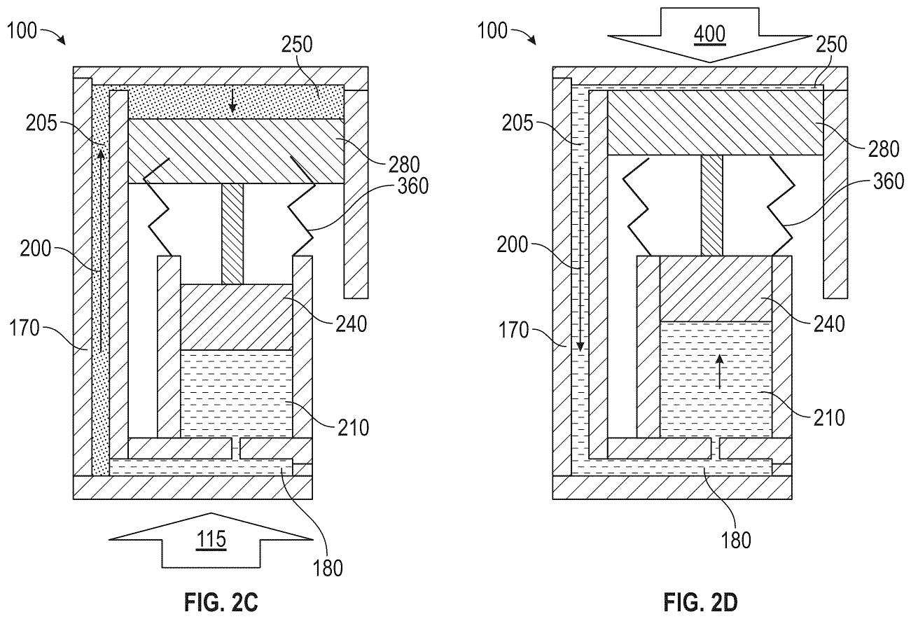

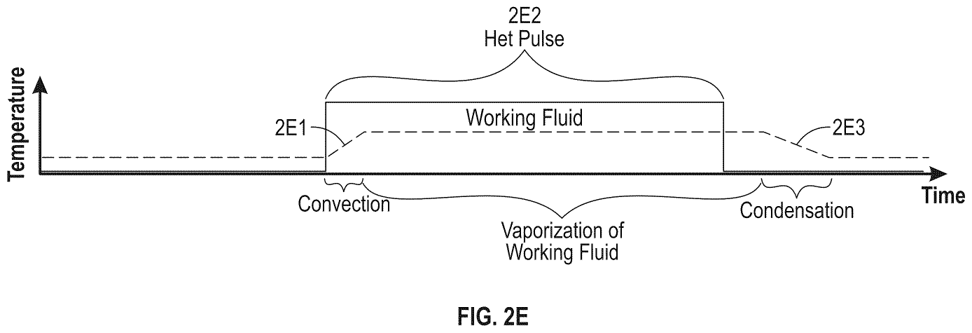

Turning to FIGS. 2A-2B and 2E, in operation, starting from the system at rest (FIG. 2A), a change of the two-phase fluid 200 to gas 205 in the bottom leg 180 of the fluid circuit 170 due to the injection of heat (FIG. 2B) by convection (FIG. 2E, at 2E1), causes the gas 205 to move upward to the top reservoir 250 via the runner leg 190. As shown in FIGS. 2C and 2E, this forces the top and bottom piston heads 280, 240 to move downward as the gas fills the top reservoir 250. Additional fluid from the bottom reservoir 210 enters the bottom leg 180 of the fluid circuit 170 from this action. The physical process of heating the fluid 200 to a gas 205, i.e., vaporization, generates a heat pulse (2E2) to move the top and bottom piston heads 280, 240 downward.

As shown in FIGS. 2D and 2E, cooling of the top plate 150 by the exterior heat sink 400, which is a continuous cooling, changes the gas 205 to the two-phase fluid 200, e.g., by condensation (2E3). From this configuration, the two-phase fluid 200 flows via the runner leg 190 of the fluid circuit 170, into the bottom leg 180 of the fluid circuit 170 and into the bottom reservoir 210, and the top and bottom piston heads 280, 240 are biased upwardly, which may be assisted by the biasing member 360. The cycle continues as more heat is directed to the system 100 when otherwise at rest (FIG. 2A).

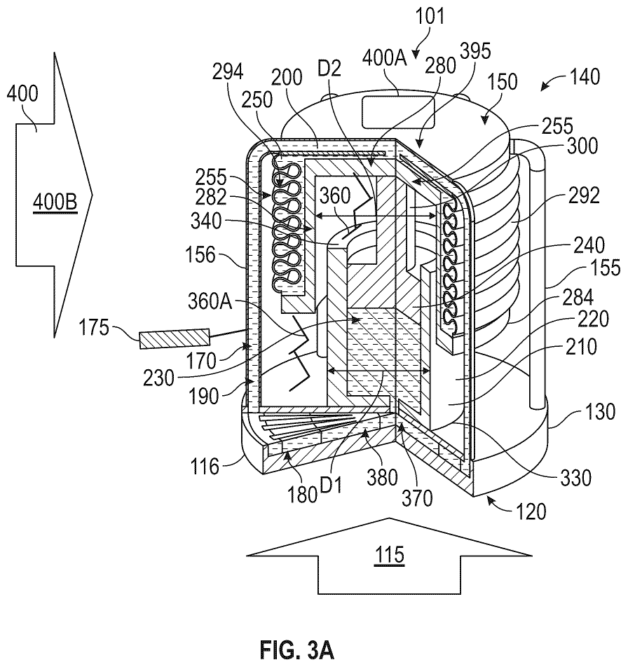

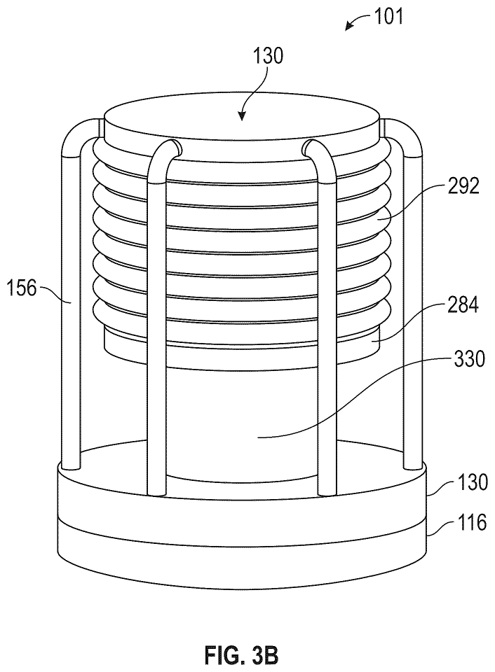

Turning to FIGS. 3A and 3B, another embodiment of a heat sink assembly 101 is shown. The assembly 101 includes a bottom (first) plate 130, at a hot side 120 of the assembly 101, that is a heat sink, which receives a heat load 115, e.g., from electronics 116 (FIG. 3B). A top (second) plate 150, located at a cold side 140 of the assembly, that is a cooling plate, and a tube 155 extending from the bottom plate 130 to the top plate 150. The top plate 150 is supported to be spaced apart from the bottom plate 130. In one embodiment, the tub 155 is rigid and provides such support, but that is not intended on limiting the scope of the embodiments.

The assembly defines a fluid circuit 170 having legs or channels. A bottom (first) leg 180 of the fluid circuit 170 extends within the bottom plate 130. A runner leg 190 of the fluid circuit 170 extends within the tube 155. A two-phase fluid 200 is in the fluid circuit 170. The fluid 200 may be a refrigerant, alcohol, water, or the like.

A bottom (first) reservoir 210 is defined by a bottom (first) piston skirt 220 having a bottom (first) piston area 230. A bottom (first) piston head 240 is located in the bottom reservoir 210. The bottom reservoir 210 is fluidly coupled to the bottom leg 180 of the fluid circuit 170.

A top (second) reservoir 250 is defined by a bellow piston 255 having a top (second) piston head 280 that is hat-shaped such that the top piston head 280 has a piston inner surface 282 and a piston bottom flange 284. An exterior bellow sleeve 292 is coupled between the top plate 150 and the piston bottom flange 284 of the top piston head 280. A cavity 294 is formed between the top piston head 280 and the bellow sleeve 292, which forms the top reservoir 250. A connecting rod 300 connects the top and bottom piston heads 280, 240. The bottom reservoir 210 is cylindrically shaped. The fluid 200 maybe filled within the circuit 170 to provide enough buoyancy to the top and bottom piston heads 280, 240 so as to prevent downward movement when the fluid 200 is entirely in a liquid form. The fluid 200 may be, e.g., injected into the circuit 170, such as by a plunger 175, and any opening from such injection may be sealed before the assembly 100 is placed in service.

There may be a plurality of the tubes 156, each similar in configuration to the tube 155, in the assembly 101, and the bottom and top plates 130, 150 may define flow manifolds that direct flow to and from the tubes 156. A bottom (first) reservoir wall 330 extends from the bottom plate 130 to a top (second) end 340 to define the bottom piston skirt 220. An outer diameter D1 of bottom reservoir wall 330 is smaller than an inner diameter D2 of the top piston head 280 so that the space between the bottom reservoir 210 and the top position head 280 is exposed to atmospheric pressure. This biases the top piston head 280 toward the top plate 150. A biasing member 360 may extend between the bottom plate 130 and the piston bottom flange 284 (biasing member 360A) and may also or alternatively extend between top end 340 of the bottom reservoir wall 330 and the top piston head 280 (biasing member 360B), to provide upward biasing forces in conditions where atmospheric pressure is low.

A bottom (first) flow aperture 370 connects the bottom reservoir 210 and the bottom leg 180 of the fluid circuit 170. The bottom flow aperture 370 defines a bottom (first) flow aperture area 380 that is smaller than the bottom piston area 230. The top plate 150 defines a top (second) flow aperture 395 for flow between the top reservoir 250 and the fluid circuit 170.

An exterior heat sink 400 may be direct cooling air toward the bellow sleeve 292 or the top plate 150. The exterior heat sink 400 may be a convective heat sink 400A, such as a fan that directs a cooling flow toward the bellow sleeve 292, or a conductive heat sink 400B, such as a cooling plate coupled to the top plate 150.

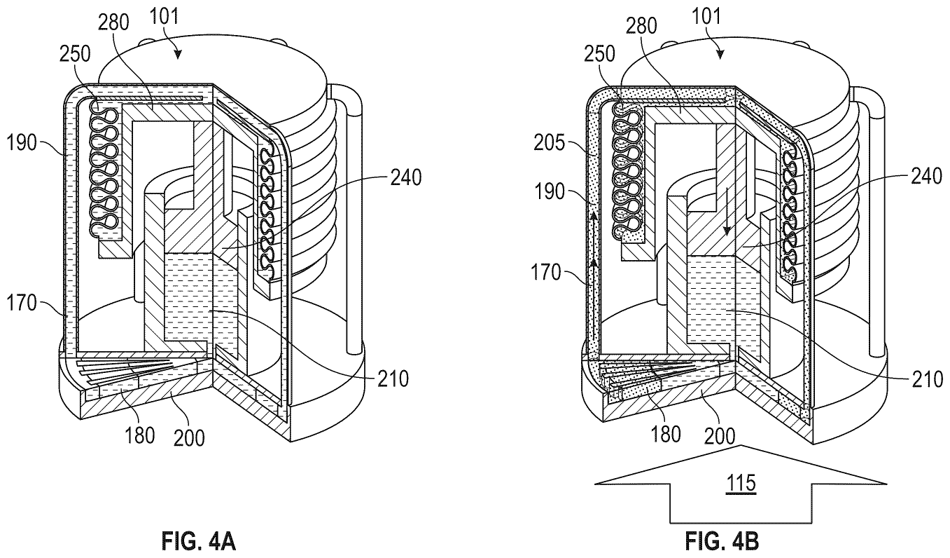

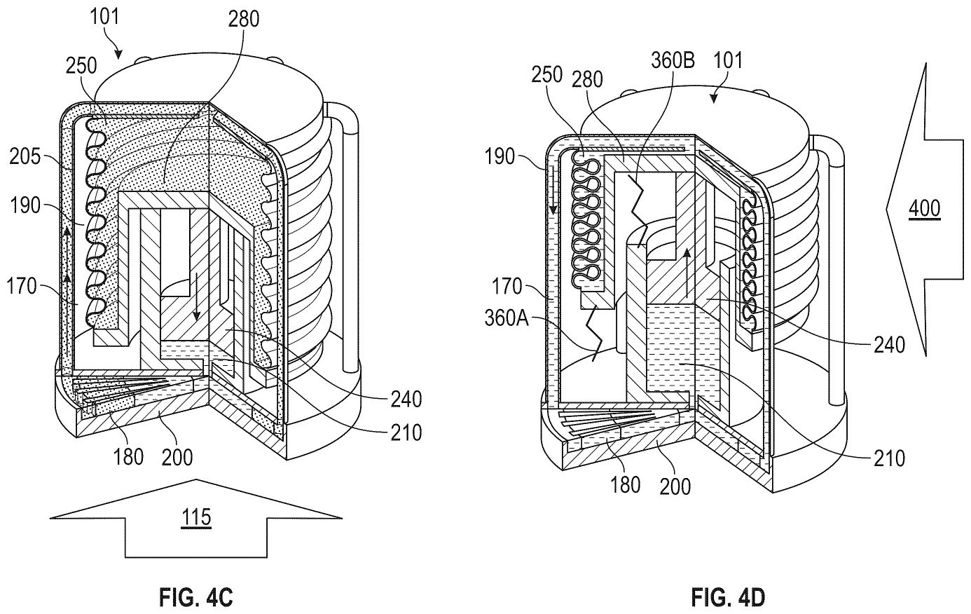

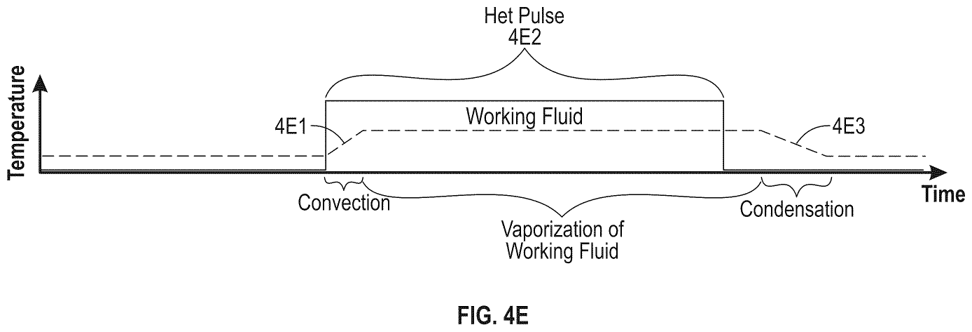

Turning to FIGS. 4A-4B and 4E, in operation, starting from the system at rest (FIG. 4A), a change of the two-phase fluid to gas 205 in the bottom leg 180 of the fluid circuit 170 due to the injection of heat (FIG. 4B) by convection (FIG. 4E, at 4E1), causes the gas 205 to move upward to the top reservoir 250 via the runner leg 190. As shown in FIGS. 4C and 4E, this forces the top and bottom piston heads 280, 240 to move downward as the gas 205 fills the top reservoir 250. Additional fluid 200 from the bottom reservoir 210 enters the bottom leg 180 of the fluid circuit 170 from this action. The physical process of heating the fluid 200 to a gas 205, i.e., vaporization, generates a heat pulse (4E2) to move the top and bottom piston heads 280, 240 downward.

As shown in FIGS. 4D and 4E, cooling of the top plate 150 or the bellow sleeve 292 by the exterior heat sink 400 changes the gas 205 to the two-phase fluid 200, e.g., by condensation (4E3). From this configuration, the two-phase fluid 200 flows via the runner leg 190 of the fluid circuit 170, into the bottom leg 180 of the fluid circuit 170 and into the bottom reservoir 210. The top and bottom piston heads 280, 240 are therefore biased upwardly, which may be assisted by the biasing member 360A along with or alternatively by biasing member 360B. The cycle continues as more heat is directed to the assembly 101 when otherwise at rest (FIG. 4A).

With the above embodiments, phase change of the fluid (e.g., a cooling media) 200 can improve cooling capacity performance for periodically high heat loaded small-planform applications. Phase transformation of the fluid 200 can have orders of magnitude higher specific capacity compared with sensible heat capacity, and therefore more heat can be removed, absorbed and transferred away from a heat load such as electronics or microelectronics without an increase in temperature. The embodiments provide a self-energized device using a two phase fluid 200 as the active cooling media for periodically heat loaded applications where a high heat load pulse is applied for a period of time, and a steady continuous cooling is used to remove the heat from the system. The embodiments utilize impingement, forced convection and phase change of the working fluid 200 to maximize heat transfer in assemblies 100, 101 having compact packaging.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

Those of skill in the art will appreciate that various example embodiments are shown and described herein, each having certain features in the particular embodiments, but the present disclosure is not thus limited. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. A heat sink assembly, comprising:
a housing having a first plate that receives a heat load, a second plate that is a cooling plate, and a sidewall extending from the first plate to the second plate,
wherein the housing defines a fluid circuit, with a first leg of the fluid circuit extending within the housing along the first plate, and a runner leg of the fluid circuit extending within the housing along the sidewall;
a two-phase fluid in the fluid circuit;
a first reservoir, defined by a first piston skirt having a first piston area, fluidly coupled to the first leg of the fluid circuit, and a first piston head is located in the first reservoir;
a second reservoir, defined by a second piston skirt having a second piston area, fluidly coupled to the runner leg of the fluid circuit, wherein the second piston area is larger than the first piston area, and a second piston head is located in the second reservoir; and
a connecting rod connecting the second and first piston heads.

2. The assembly of claim 1, wherein the first reservoir is cylindrically shaped.

3. The assembly of claim 1, wherein the second reservoir is cylindrically shaped.

4. The assembly of claim 1, wherein
the first leg of the fluid circuit is defined by an inner first wall;
the runner leg of the fluid circuit is defined by an inner sidewall;
the first reservoir is defined by a first reservoir wall extending to a second end; and
the second reservoir is defined at least partially by the inner sidewall.

5. The assembly of claim 4, wherein
a segment of the inner sidewall is isolated from the runner leg of the fluid circuit and defines an aperture such that the second and first piston heads and the connecting rod are exposed to atmospheric pressure, to bias the second piston head toward the second plate.

6. The assembly of claim 5, wherein a biasing member extends from the second end of the first reservoir wall toward the second piston head.

7. The assembly of claim 6, wherein the biasing member is a spring.

8. The assembly of claim 6, wherein the inner first wall defines a first flow aperture having a first flow aperture area that is smaller than the first piston area, for flow between the first reservoir and the fluid circuit.

9. The assembly of claim 6, wherein
the inner sidewall defines a sidewall flow aperture for flow between the second reservoir and the fluid circuit.

10. The assembly of claim 1, wherein, in operation:
a change of the two-phase fluid to gas in the first leg of the fluid circuit causes the gas to move upward to the second reservoir via the runner leg, forcing the second and first piston heads to move downward as the gas fills the second reservoir and additional fluid from the first reservoir enters the first leg of the fluid circuit; and
cooling of the second plate changes the gas to the two-phase fluid, whereby the two-phase fluid flows via the runner leg of the fluid circuit, into the first leg of the fluid circuit and into the first reservoir, and the second and first piston heads are biased upwardly.

11. The assembly of claim 1, including an exterior heat sink connected to the second plate.

12. The assembly of claim 11, wherein the exterior heat sink is a conductive or convective heat sink.

13. A heat sink assembly, comprising:
a first plate that receives a heat load, a second plate that is a cooling plate and is supported so as to be spaced apart from the first plate, and a tube extending from the first plate to the second plate,
wherein the assembly defines a fluid circuit, with a first leg of the fluid circuit extending within the first plate, and a runner leg of the fluid circuit extending within the tube;
a two-phase fluid in the fluid circuit;
a first reservoir, defined by a first piston skirt having a first piston area, fluidly coupled to the first leg of the fluid circuit, and a first piston head is located in the first reservoir;
a second reservoir, defined by a bellow piston having a second piston head that is hat-shaped such that the second piston head has a piston inner surface and a piston first flange, and an exterior bellow sleeve coupled between the second plate and the piston first flange of the second piston head, wherein a cavity between the second piston head and the bellow sleeve defines the second reservoir,
a connecting rod connecting the second and first piston heads.

14. The assembly of claim 13, wherein the first reservoir is cylindrically shaped.

15. The assembly of claim 14, wherein
the first plate defines a first flow aperture defining a first flow aperture area that is smaller than the first piston area, for flow between the first reservoir and the fluid circuit.

16. The assembly of claim 15, wherein
the second plate defines a second flow aperture for flow between the second reservoir and the fluid circuit.

17. The assembly of claim 13, wherein, in operation:
a change of the two-phase fluid to gas in the first leg of the fluid circuit causes the gas to move upward to the second reservoir via the runner leg, forcing the second and first piston heads to move downward as the gas fills the second reservoir and additional fluid from the first reservoir enters the first leg of the fluid circuit; and
cooling of the second plate or the bellow sleeve changes the gas to the two-phase fluid, whereby the two-phase fluid flows via the runner leg of the fluid circuit, into the first leg of the fluid circuit and into the first reservoir, and the second and first piston heads are biased upwardly.

18. The assembly of claim 13, including an exterior heat sink operationally coupled to the second plate or the bellow sleeve.

19. The assembly of claim 18, wherein the exterior heat sink is a conductive or convective heat sink.
